(19) United States
(12) Patent Application Publication
(10) Pub. No.: US 2003/0141016 A1
(43) Pub. Date: Jul. 31, 2003

(54) Exhaust system for processing apparatus

(76) Inventors: Wataru Okase, Sagamihara-Shi (JP); Noriaki Matsushima, Sagamihara-Shi (JP); Akihiko Tsukada, Sagamihara-Shi (JP); Akihiko Hiroe, Kofu-Shi (JP); Kouji Shimomura, Kofu-Shi (JP)

Correspondence Address: SMITH, GAMBRELL & RUSSELL, LLP, 1850 M STREET, N.W., SUITE 800, WASHINGTON, DC, 20036, US

(21) Appl. No.: 10/354,097

(22) Filed: Jan. 30, 2003

Related U.S. Application Data
(63) Continuation of application No. 09/627,000, filed on Jul. 27, 2000, now abandoned.

(30) Foreign Application Priority Data
Jul. 27, 1999 (JP) 1999-212873

(51) Int. Cl. C23F 1/00; C23C 16/00

(52) U.S. Cl. 156/345.29; 118/715

(57) ABSTRACT

In an exhaust system for a processing apparatus wherein a processing gas is used to subject a semiconductor wafer W to be processed to a predetermined processing, a vacuum exhaust pathway 40 having a vacuum pump 42 is connected to the processing apparatus 20. A trap mechanism 52 for removing reaction products that flow into the vacuum exhaust pathway 40 is provided within the vacuum exhaust pathway 40, via disconnectable connection flanges 78 and 86 on the upstream side of the vacuum pump 42. An upstream-side inlet portion and an outlet portion of this trap mechanism 52 are provided with isolation valves 80 and 88 that can place the interior of the trap mechanism in a hermetically sealed state when necessary. A bypass pathway 54 is provided to allow a cleaning gas to bypass the trap mechanism 52 during the cleaning of the processing apparatus 20. It is possible to perform maintenance work without exposing the interior of the trap mechanism 52 to the atmosphere by separating the connection flanges 78 and 86 and then removing the trap mechanism 52.

### BACKGROUND OF THE INVENTION

1. Technical Field

The present invention relates to an exhaust system for a processing apparatus such as one for forming a film on an object to be processed such as a semiconductor wafer.

2. Description of Related Art

During the fabrication of a semiconductor device, it is usual to fabricate a desired device by repeating various processes such as film-formation and patterning on a semiconductor wafer. The specifications for such film-formation techniques are becoming stricter year by year as semiconductor devices become smaller and more tightly integrated, raising demands for even thinner films, such as extremely thin oxide films used as the insulation films of capacitors or gate insulation films within the devices, so there is a demand for highly accurate control over film thicknesses.

Silicon oxide films or silicon nitride films can be used as these insulation films. There is a recent trend towards using films of metal oxides, such as tantalum oxide (Ta₂O₃), as materials that have better insulating characteristics. These metal oxide films exhibit highly reliable insulating properties even when thin, so they are becoming common in many applications.

Taking the formation of a tantalum oxide film as an example of this formation of a metal oxide film, Japanese Patent Application Laid-Open No. 2-283022 discloses the use of pentaethoxytantalum (Ta(OC₂H₅)₅), a typical metal alkoxide, as the source material for the film-formation. The tantalum alkoxide is supplied to the film-formation unit together with nitrogen as a carrier gas, while bubbling nitrogen through the tantalum alkoxide, and semiconductor wafers are maintained at a processing temperature of 400° C., by way of example, so that a tantalum oxide (Ta₂O₅) film is deposited thereon by chemical vapor deposition (CVD). Japanese Patent Application Laid-Open No. 10-79378, on the other hand, disclosed a technique of sending a liquid source material under the pressure of an inert gas, while controlling the flowrate thereof, to turn it into a gas, then supplying it in a gaseous state to the film-formation unit for forming the film.

In all film-formation processes, not just those described above, unreacted processing gas and reaction products formed by the reactions are expelled in a gaseous state within the exhaust gases from the processing apparatus. A trap mechanism is generally provided within the exhaust system, for removing unreacted processing gas and harmful gases such as those of the reaction products from the exhaust gases, from the viewpoints of preventing atmospheric pollution and bad effects to the human body due to the unreacted processing gas and reaction products.

This trap mechanism will be described with reference to FIG. 3, which shows a processing apparatus and a standard exhaust system that is connected thereto. As shown in this figure, a film-formation gas such as pentaethoxytantalum in gaseous form is introduced into a processing vessel 4 of a processing apparatus 2 from a shower head 6, and a film of a substance such as tantalum oxide is deposited at a predetermined processing temperature and at a predetermined temperature of the surface of a semiconductor wafer W that is mounted on a mounting stand 8. A vacuum exhaust pathway 12 that forms an exhaust system is connected to exhaust ports 10 of this processing vessel 4, a trap mechanism 14 and a vacuum pump 16 are connected in that order to the vacuum exhaust pathway 12, and the configuration is such that the interior of the processing vessel 4 is evacuated and also reaction products and any remaining film-formation gas within the exhaust gases are removed by means such as liquefaction by cooling with a cooling medium.

If film-formation processing is done on a certain number of wafers in this processing apparatus, a cleaning gas such as ClF₃ is made to flow into the processing vessel 4 to perform a cleaning process, in order to prevent the formation of imperfect films due to factors such as particles adhering to the interior of the processing vessel 4.

However, captured substances in a liquid form, sticky liquid form, or powder form (depending on the type of film-formation gas that is used) will gradually accumulated in the above described trap mechanism 14, necessitating periodic or non-periodic maintenance to remove those substances or perform spot checks.

Since the trap mechanism 14 is removed from the vacuum exhaust pathway 12 during this maintenance, this causes problems in that the interior thereof is exposed to the atmosphere, there may be reactions with the oxygen in the atmosphere (depending on the type of gas and the reaction products), a sticky substance may suddenly become an extremely sticky product, and it is not easy to clean off such substances. If the reaction products react with the cleaning gas, such as ClF₃, in particular, they may become even stickier and more difficult to remove.

When the trap mechanism 14 itself has been removed, bad smells from the captured substances therein will spread to the exterior, which will not only deteriorate the working environment of the maintenance workers, it will also adversely affect their health in the worst case.

The present invention was devised in the light of the above problems and is intended to provide an exhaust system for a processing apparatus that can solve those problems effectively. The object thereof is to provide an exhaust system for a processing apparatus that makes it possible to prevent exposure of the interior of a trap mechanism to the atmosphere during maintenance.

### SUMMARY OF THE INVENTION

In order to achieve the above object, the present invention provides an exhaust system for a processing apparatus for subjecting an object to be processed to a predetermined processing with a processing gas, wherein the exhaust system comprises: a vacuum exhaust pathway connected to the processing apparatus; a vacuum pump provided in the vacuum exhaust pathway, for evacuating the processing apparatus; a trap mechanism for removing reaction products that are generated within the processing apparatus and flow into the vacuum exhaust pathway, the trap mechanism being provided within the vacuum exhaust pathway, so as to divide the pathway into an upstream-side section and a downstream-side section; an upstream connection device for removably linking an inlet portion of the trap mechanism to the upstream-side section; a downstream connection device for removably linking an outlet portion of the trap mechanism to the downstream-side section; an inlet-side isolation valve and an outlet-side isolation valve connected in a closable manner to the inlet portion and the outlet portion of the trap mechanism, for placing an interior of the trap mechanism in a hermetically sealed state; and a bypass pathway for connecting the upstream-side section and the downstream-side section of the vacuum exhaust pathway, bypassing the upstream connection device, the trap mechanism, and the outlet-side isolation valve, to allow a cleaning gas to bypass the trap mechanism and flow through the vacuum exhaust pathway during the cleaning of the processing apparatus.

The above described configuration ensures that the exhaust gases flow into the trap mechanism during the usual processing such as film-formation, and the reaction products are removed from the exhaust gases. The cleaning gas flows through the bypass pathway during the cleaning, so it does not flow within the trap mechanism. This ensures that the reaction products do not come into contact with the cleaning gas, thus preventing any reactions between them. The interior of the trap mechanism is hermetically sealed during maintenance of the trap mechanism by closing the isolation valves at the inlet and outlet portions thereof. In this state, the linkages of the connection devices can be released so that the trap mechanism can be removed from the vacuum exhaust pathway. Since the interior of the trap mechanism is held in a hermetically sealed state during this time, as described above, the reaction products that have been captured within the trap mechanism are not exposed to the atmosphere, thus making it possible to prevent the generation of bad smells or oxides that are harmful to the human body. There are no reactions between the captured reaction products and the cleaning gas or the atmosphere, so there is no further change of the reaction products into highly sticky substances or solids, thus making it possible to perform the job of cleaning and removing them rapidly.

The exhaust system may be further provided with a shut-off valve that is provided on an immediately upstream side of the upstream-side connection means within the upstream-side section of the vacuum exhaust pathway. Similarly, the exhaust system may be further provided with a reverse-flow prevention valve that is provided on an immediately downstream side of the downstream-side connection device within the downstream-side section of the vacuum exhaust pathway. Further, the exhaust system may also be provided with a bypass valve in an upstream end portion of the bypass pathway.

The upstream-side connection device and the downstream-side connection device are each preferably configured of connection flanges.

The exhaust system may be further provided with a liquid collection vessel connected to the trap mechanism, for collecting the reaction products that have been captured as liquids therein.

The exhaust system may be further provided with a liquid collection vessel valve between the trap mechanism and the liquid collection vessel, for controlling the flow of reaction products from the trap mechanism to the liquid collection vessel.

The exhaust system may be further provided with a drain pipe within the liquid collection vessel, for expelling the reaction products that have collected as liquids therein. The exhaust system is preferably provided with a cleaning mechanism within the trap mechanism, for washing away liquefied reaction products that have been captured therein. The vacuum exhaust pathway is preferably inclined downward at a predetermined angle towards the downstream side, in at least the portion thereof in which the trap mechanism is provided.

### BRIEF DESCRIPTION OF THE DRAWINGS

FIG. 1 shows the piping layout of a typical exhaust system for a processing apparatus in accordance with the present invention;

FIG. 2 shows the piping layout of a modified exhaust system of this invention; and

FIG. 3 shows the piping layout of an processing apparatus and a prior-art exhaust system connected thereto.

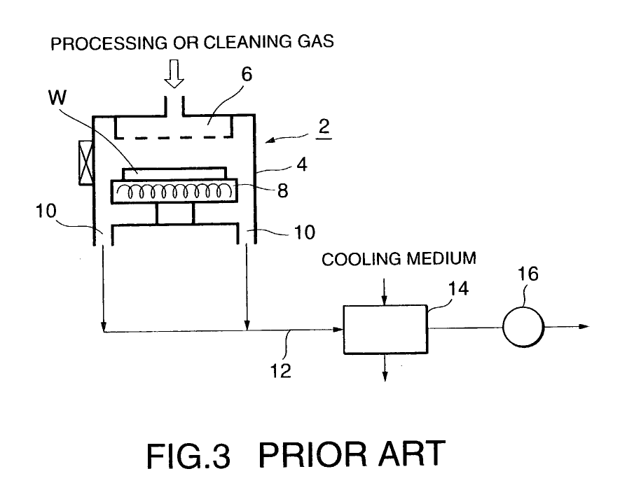

### DESCRIPTION OF THE PREFERRED EMBODIMENTS

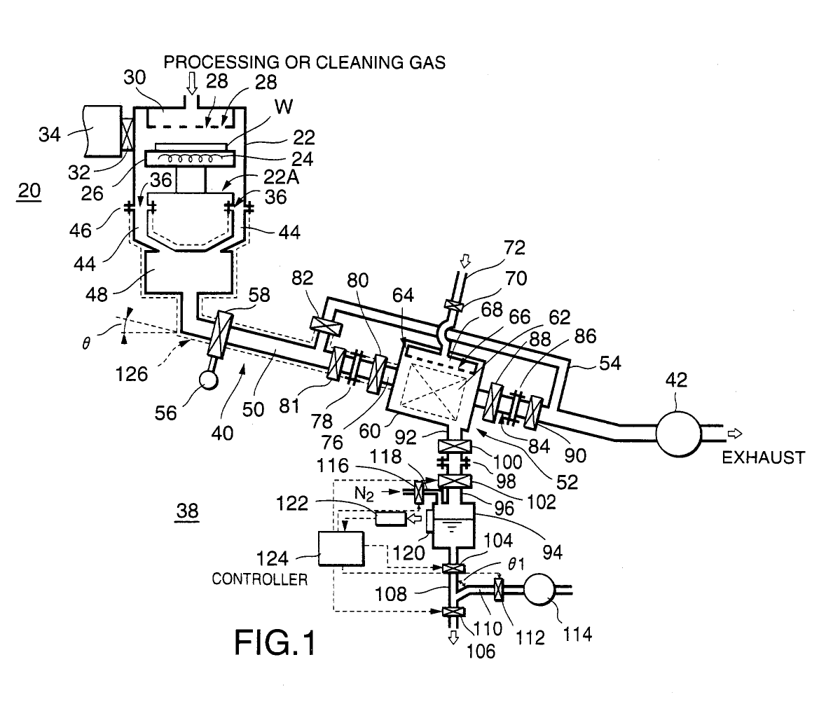

An embodiment of an exhaust system for a processing apparatus in accordance with the present invention will be described below with reference to the accompanying drawings. The piping layout of a typical exhaust system for a processing apparatus is shown in FIG. 1. The description in this case concerns a processing apparatus that uses pentaethoxytantalum (Ta(OC₂H₅)₅) as a metal alkoxide for forming films of tantalum oxide, by way of example. As shown in this figure, a film-formation apparatus 20 that is a processing apparatus has a circular cylindrical processing vessel 22 made of a material such as aluminum. Amounting stand 26 with an internal heater 24 is provided within this processing vessel 22, erected from a base portion thereof, where the mounting stand 26 is configured in such a manner that a semiconductor wafer W that is an object to be processed can be mounted on the upper surface thereof. A shower head 30 having a plurality of gas ejection ports 28 in the lower surface thereof is provided in a ceiling portion of the processing vessel 22, with the configuration being such that a film-formation gas of pentaethoxytantalum can be introduced into the processing vessel 22 as a processing gas. A load-lock chamber 34 is connected to a conveyor port in a side wall of the processing vessel 22, with an openable/closable gate valve 32 therebetween that permits the conveying of a wafer W therethrough.

A plurality of exhaust ports 36 are provided at a substantially uniform distribution in a bottom portion 22A of the processing vessel 22 and these exhaust ports 36 are connected to an exhaust system 38. Usually about four of the exhaust ports 36 are provided. More specifically, the exhaust system 38 mainly comprises a vacuum exhaust pathway 40 made of a material such as stainless steel and a vacuum pump 42 that is provided in a downstream side thereof, with the configuration being such that the interior of the processing vessel 22 can be evacuated thereby. Branch pipes 44 corresponding to the exhaust ports 36 are connected to the upstream part of the vacuum exhaust pathway 40 and these branch pipes 44 are each connected to the exhaust ports 36 by flanges 46. A collection box 48 is connected in common to downstream ends of the branch pipes 44 and a main pipeline 50 of the vacuum exhaust pathway 40 extends from this collection box 48.

A pressure adjustment valve 58 that is driven by a drive motor 56 is provided partway along the main pipeline 50, with the configuration being such that the pressure within the processing vessel 22 is adjusted automatically by this pressure adjustment valve 58. There are provided a trap mechanism 52, which is characterized in accordance with the present invention, and a bypass pathway 54, which is connected between the upstream and downstream sides of the trap mechanism 52 to divert the flow of gas if necessary, on the downstream side of the pressure adjustment valve 58.

The trap mechanism 52 comprises a box-shaped trap vessel 60 that is formed of a material such as stainless steel so as to surround the entire mechanism, and a plurality of cooling fins 62 that provide cooling by the flow of a coolant are accommodated therein. The configuration is such that the exhaust gases that are introduced therein are cooled so that the processing gases and reaction products that are in a gaseous state are re-liquefied and trapped from the exhaust gases, then the liquefied reaction products are removed. A cleaning mechanism 64 is provided above the cooling fins 62. This cleaning mechanism 64 is provided so as to cover the entire area above the cooling fins 62 and has a cleaning shower head 68 that has a plurality of cleaning liquid ejection ports 66 in the lower surface thereof.

A cleaning pipeline 72 having a cleaning valve 70 therein is connected to this cleaning shower head 68, with the configuration being such that a cleaning liquid such as ethanol can be supplied as required by the pressure of a gas such as nitrogen, then ejected from the cleaning shower head 68.

An inlet pipe 76 for introducing gases is provided at one end of the trap vessel 60, with the other end portion thereof being connected by upstream-side connection flanges 78 to the downstream end of the upstream section of the vacuum exhaust pathway 40. An upstream-side isolation valve 80 is also provided in the inlet pipe 76, to seal off the interior of this pipe when necessary. A shut-off valve 81 for opening and closing the vacuum exhaust pathway 40 is provided in that pathway 40 between the upstream-side connection flanges 78 and the branch point of the bypass pathway 54. A bypass valve 82 for opening and closing the bypass pathway 54 is provided in a portion in the vicinity of the upstream end of this pathway 54, with the configuration being such that the bypass pathway 54 can be opened or closed as necessary.

An outlet pipe 84 for extracting gases is provided at the other end of the trap vessel 60, with the other end portion thereof being connected by downstream-side connection flanges 86 to a downstream-side section of the vacuum exhaust pathway 40. An downstream-side isolation valve 88 is also provided in the outlet pipe 84, to seal off the interior of this pipe when necessary. It is therefore possible to isolate the interior of the trap vessel 60 from the upstream-side and downstream-side sections of the vacuum exhaust pathway 40 by closing both of the upstream-side and downstream-side valves 80 and 88.

A reverse-flow prevention valve 90 for opening and closing the vacuum exhaust pathway 40 is provided in the downstream-side section of that pathway 40 between the downstream-side connection flanges 86 and the point at which the bypass pathway 54 joins. The portion of the vacuum exhaust pathway 40 that is within the trap mechanism 52 is inclined downward at a predetermined angle to the horizontal, towards the downstream side of the flow of exhaust gases, to prevent backflow of the liquefied captured substances within the trap mechanism 52.

A downward-extending waste liquid pipe 92 is connected to the lowermost end of the bottom of the trap vessel 60, in other words, at the right-hand end of the bottom in FIG. 1, and the lower end of this waste liquid pipe 92 is connected by flanges 98 to the upper end of a liquid collection pipe 96 that extends from a liquid collection vessel 94. This ensures that the liquefied captured substances that collect within the trap vessel 60 can flow downward within the waste liquid pipe 92 and the liquid collection pipe 96 and accumulate in the liquid collection vessel 94.

An exhaust liquid valve 100 for opening and shutting the waste liquid pipe 92 is provided therein, and a liquid collection vessel valve 102 for opening and closing the liquid collection pipe 96 is similarly provided therein. A drain pipe 108 having a first valve 104 and a second valve 106 partway therealong is connected to the bottom portion of the liquid collection vessel 94, so that substances that have accumulated within the liquid collection vessel 94 can be expelled out of the system if necessary.

A branch pipe 110 that is inclined upward at a predetermined angle θ1 is formed to branch off from the drain pipe 108 between the first valve 104 and the second valve 106, and a valve 112 and a vacuum pump 114 are interposed within this branch pipe 110. Note that the vacuum pump 114 need not be interposed within the branch pipe 110; it could also be connected immediately upstream of the vacuum pump 42 that is interposed within the vacuum exhaust pathway 40.

An inert gas introduction pipe 118 provided with an inert gas valve 116 partway therealong is connected to the ceiling portion of the liquid collection vessel 94, with the configuration being such that an inert gas such as nitrogen can be introduced into the liquid collection vessel 94 if necessary. An observation window 120 of a material such as quartz is provided in a side wall of the liquid collection vessel 94 and an optical accumulated substances sensor 122 is provided for observing through this observation window 120 and detecting the amount of accumulated substances (reaction products) within the liquid collection vessel 94. If the accumulation of a predetermined amount of accumulated substances is detected by the accumulated substances sensor 122, a controller 124 controls the opening and closing of the valves to ensure that the accumulated substances within the liquid collection vessel 94 are expelled out of the system. Note that a liquid-surface detector that detects the liquid level within the liquid collection vessel 94 could also be provided as the accumulated substances sensor 122. In addition, another observation window could be provided in a side wall of the trap vessel 60, to enable observation of that interior.

A tape heater 126 is wound as a thermal insulation means around the vacuum exhaust pathway 40, the valves 58 and 80, the collection box 48, and the branch pipes 44 between the exhaust ports 36 of the processing vessel 22 and the trap vessel 60, to heat them to a temperature of 160° C., by way of example, to prevent the gaseous reaction products within the exhaust gases from condensing in an intermediate portion.

The description now turns to the operation of this embodiment, configured as described above.

First of all, an unprocessed semiconductor wafer W is introduced into the processing vessel 22 through the gate valve 32, which is open, and is mounted on the mounting stand 26. The environment within the processing vessel 22 has already been evacuated through the vacuum exhaust pathway 40 by the vacuum pump 42, which was driven beforehand. The wafer W is then heated by the heater 24 and is held at a predetermined processing temperature and also pentaethoxytantalum in a gaseous form is introduced as a processing gas from the shower head 30 into the processing vessel 22. Simultaneously therewith, the interior of the processing vessel 22 is maintained at a predetermined pressure by adjustment of the pressure adjustment valve 58 provided in the main pipeline 50 of the vacuum exhaust pathway 40, and a film such as one of tantalum oxide is affixed to the surface of the wafer.

During this film-formation process, exhaust gases from the processing vessel 22 pass within the main pipeline 50 of the vacuum exhaust pathway 40, but the bypass valve 82 provided within the bypass pathway 54 is closed so that they do not pass into the bypass pathway 54. In other words, the environment within the processing vessel 22 is exhausted through the exhaust ports 36 provided in the bottom of the vessel, flow out within the branch pipes 44, and are captured within the collection box 48. These exhaust gases flow within the main pipeline 50 then flow into the trap vessel 60 through the inlet pipe 76 of the trap mechanism 52, are expelled from the trap vessel 60 through the outlet pipe 84, once again flow into the main pipeline 50 on the downstream side, and finally are expelled out of the system by the vacuum pump 42.

In this case, the exhaust gases that have flowed into the trap vessel 60 come into contact with the cooled cooling fins 62 provided within the trap vessel and are cooled thereby, the remaining unreacted processing gas and reaction products that were in a gaseous state are condensed and liquefied, and these liquids are trapped, adhering to the cooling fins 62 and other surfaces. Thus no film-formation gas and reaction product gases remain within the exhaust gases expelled from the trap mechanism 52.

Since the main pipeline 50 of the vacuum exhaust pathway 40 is inclined downward by the angle θ along the downstream side of the flow direction of the exhaust gases, there is no backflow towards the upstream side of the liquefied captured substances within the trap vessel 60 and, if the reaction products should condense within the main pipeline 50 for some reason, these will flow downward along the main pipeline 50 so that they do not flow into the trap vessel 60.

If a certain number of wafers are processed, the generation of particles on surfaces such as those of the mounting stand 26 and the inner walls of the processing vessel 22 will increase the number of imperfect films to more than permitted levels. In order to prevent this, therefore, a cleaning gas such as ClF₃ flows from the shower head 30 into the processing vessel 22 either periodically or non-periodically, to perform cleaning.

If this cleaning gas were to come into contact with the reaction products that are captured in the trap vessel 60, they would react and coagulate, causing bad smells or generating harmful gases. Therefore, this cleaning gas is made to flow within the bypass pathway 54, bypassing the trap mechanism 52.

To enable this, both of the shut-off valve 81 provided in the upstream-side section of the main pipeline 50 and the reverse-flow prevention valve 90 provided in the downstream-side section of the main pipeline 50 are closed, shutting off the flow of exhaust gases into the trap vessel 60 and also opening the bypass valve 82 provided close to the upstream end of the bypass pathway 54. This ensures that the cleaning gas does not flow within the trap vessel 60, so that it flows down into the bypass pathway 54. The cleaning gas does not come into contact with the reaction products and other substances that are captured within the trap vessel 60, so there are no reactions between the two flows that might have bad effects.

Since the reverse-flow prevention valve 90 is also closed, the cleaning gas that flows within the downstream-side section of the main pipeline 50 does not reverse and flow into the trap vessel 60. Note that the downstream-side isolation valve 88 that is provided in the outlet pipe 84 could be closed instead of the reverse-flow prevention valve 90.

The description now turns to the disposal of the liquefied substances (the reaction products) that have been captured during the film-formation processing.

As described previously by way of example, reaction products that have liquefied by the cooling fins 62 within the trap vessel 60 are captured. The liquefied captured substances flow to the lowermost end of the bottom portion of the trap vessel 60, then flow further downward because the exhaust liquid valve 100 provided in the waste liquid pipe 92 and the liquid collection vessel valve 102 provided in the liquid collection pipe 96 are both open, and are finally collected within the liquid collection vessel 94 which is initially in an evacuated state.

Thus the liquefied reaction products that have been captured within the trap vessel 60 then proceed to be collected within the liquid collection vessel 94, so that the reaction products do not remain in significant quantities within the trap vessel 60, and therefore the liquefied reaction products can be prevented from returning and flowing back into the processing vessel 22 from the trap vessel 60, even if the exhaust gases should flow backward for some reason during the film-formation process.

If a certain quantity of the liquefied accumulated substances does collect within the liquid collection vessel 94, that quantity is detected by the accumulated substances sensor 122 through the observation window 120, then it can be automatically expelled to outside of the system. In other words, if the accumulated substances sensor 122 detects an accumulated quantity that exceeds a predetermined value, the operation of the controller 124 is activated. First of all, the liquid collection vessel valve 102 is shut to halt the downward flow of the reaction products from above that valve, then the inert gas valve 116 of the inert gas introduction pipe 118 is opened to introduce an inert gas such as nitrogen into the spaces of the liquid collection vessel 94. The liquefied accumulated substances within the liquid collection vessel 94 are made to flow down into the drain pipe 108 by opening the first and second valves 104 and 106 of the drain pipe 108, so that they are expelled out of the system. If it is not desirable to expose the expelled liquefied accumulated substances to the atmosphere in this case, the configuration could be such that the liquefied accumulated substances within the liquid collection vessel 94 are expelled into a vessel that is filled with a gas such as nitrogen. The liquefied accumulated substances flowing down through the drain pipe 108 do not flow into the branch pipe 110 which is connected thereto at the angle of inclination of 1.

Once the expulsion of the liquefied accumulated substances from within the liquid collection vessel 94 is completed, the inert gas valve 116 and the second valve 106 are closed and the interior of the liquid collection vessel 94 is evacuated by activating the vacuum pump 114 provided in the branch pipe 110. Once this evacuation is completed, the accumulation within the liquid collection vessel 94 is re-started by again opening the liquid collection vessel valve 102 with the valve 112 and the first valve 104 closed. In this manner, the accumulated substances within the liquid collection vessel 94 can be automatically expelled out of the system.

The description now concerns the procedure required during maintenance of the trap mechanism 52. First of all, the shut-off valve 81 and the reverse-flow prevention valve 90, which are provided in the main pipeline 50 of the vacuum exhaust pathway 40, the upstream-side isolation valve 80 of the inlet pipe 76, and the downstream-side isolation valve 88 of the outlet pipe 84 are all closed. This isolates the interior of the trap vessel 60 from the main pipeline 50. If the cleaning mechanism 64 is provided in the trap mechanism 52, the cleaning valve 70 of the cleaning pipeline 72 is then opened so that a substance such as methanol is ejected as a cleaning liquid from the cleaning shower head 68 to wash away the liquefied captured substances adhering to the cooling fins 62. This cleaning liquid flows downward and collects in the liquid collection vessel 94. Note that the cleaning liquid is not limited to the above-mentioned methanol.

Once this cleaning operation has been completed, the cleaning valve 70, the exhaust liquid valve 100, and the liquid collection vessel valve 102 are all closed. This isolates the interior of the trap vessel 60, placing it into a completely sealed state. In this state, the upstream-side connection flanges 78 and the downstream-side connection flanges 86 connected to the main pipeline 50 of the trap mechanism 52 and the flanges 98 of the lower end of the waste liquid pipe 92 can all be disconnected by loosening the linking bolts or the like. This ensures that the trap mechanism 52 can be removed as a unit so that it can be moved to a convenient location for maintenance cleaning or the like.

In this case, any reaction products that remain in the trap vessel 60 after the cleaning do not come into contact with the atmosphere because the interior of the trap vessel 60 is sealed, and no inconvenient reaction or the like is generated due to the cleaning operation or the work.

If the cleaning mechanism 64 is not provided, the above effect becomes even greater because the liquefied captured substances adhere to the surfaces of the cooling fins 62. If the liquid collection vessel 94 is not provided, the liquefied captured substances will collect on the bottom portion of the trap vessel 60, making the above effect even more obvious. In addition, portions other than the trap mechanism 52 are maintained in an evacuated state, even during the maintenance period.

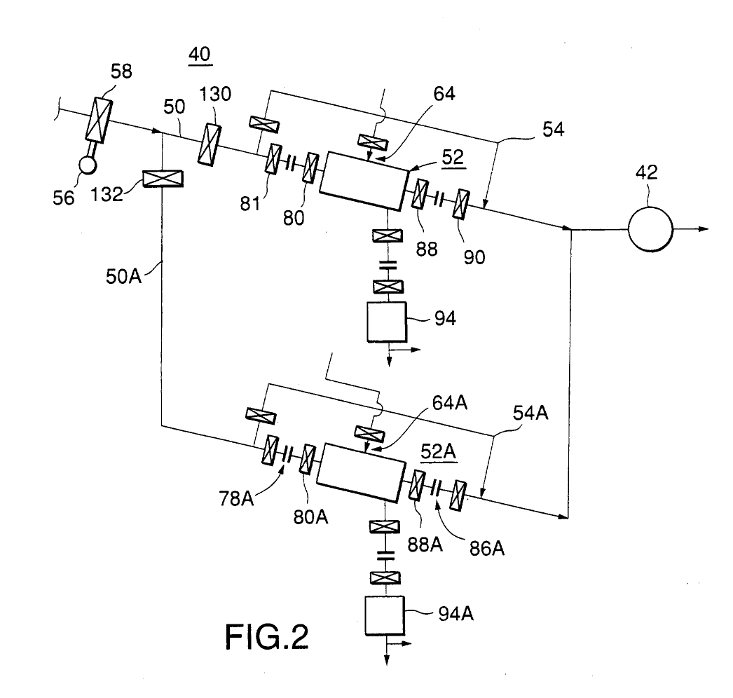

Note that the above embodiment of this invention is provided with a single assembly of the trap mechanism 52, the bypass pathway 54, and the accompanying equipment, but the present invention is not limited thereto and thus the main pipe could branch into two portions with two sets of the above-described equipment connected thereto. A schematic piping layout of a modified exhaust system of this invention is shown in FIG. 2. Note that components that are the same as those in FIG. 1 are denoted by the same reference numbers and further description thereof is omitted. As shown in this figure, a branch main pipeline 50A is provided, branching off of the main pipeline 50 of the vacuum exhaust pathway 40 and bypassing all of the trap mechanism 52 and the bypass pathway 54. Components such as a trap mechanism 52A, a bypass pathway 54A, a cleaning mechanism 64A, a liquid collection vessel 94A, upstream-side and downstream-side connection flanges 78A and 86A, and upstream-side and downstream-side isolation valves 80A and 88B are provided for this main pipeline 50A, of the same configuration as previously described. First and second switching valves 130 and 132 are provided in the vicinity of the upstream ends of the main pipeline 50 and the branch main pipeline 50A, respectively, to enable switching between the pipes 50 and 50A.

Either the trap mechanism 52 or the trap mechanism 52A is selected for use by switching those first and second switching valves 130 and 132. Since this makes it possible to have one trap mechanism operating even which the other trap mechanism is undergoing maintenance, the trap mechanisms can be switched for maintenance without halting the operation of the film-formation apparatus.

Note that the above embodiments of this invention were described as relating to the formation of films of tantalum oxide by way of example, but the type of film is not limited thereto and thus the present invention can be applied to the formation of other types of film, such as nitride films. In addition, the present invention is not limited to film-formation apparatuses; it can be applied to all other processes that require trap mechanisms. Similarly, the present invention was described above as relating to a single-wafer processing apparatus, but it can also be applied to a processing apparatus in which a plurality of semiconductor wafers are processed at a time.

Furthermore, a semiconductor wafer was used above as an example of the object to be processed, but the present invention is not limited thereto and it can equally well be applied to apparatuses that process other substrates such as LCD substrates or glass substrates.

Use of the above-described exhaust system for a processing apparatus in accordance with this invention makes it possible to obtain the excellent operational effects discussed below.

Since a bypass pathway is provided to enable the cleaning gas to bypass the trap mechanism, so that the cleaning gas does not flow through the trap mechanism, it is possible to prevent contact between the captured substances and the cleaning gas, thus preventing mutual reactions. In addition, the interior of the trap mechanism can be placed in a sealed state by the isolation valves during maintenance so that the captured substances are not exposed to the atmosphere, which not only prevents the generation of bad smells and oxides that are harmful to the human body, it also increases the efficiency of maintenance work such as cleaning.

The provision of the liquid collection vessel for collecting the reaction products and the configuration by which those reaction products are collected within that vessel ensure that the reaction products can be prevented from flowing back into the processing apparatus, even if the flow of exhaust gases should reverse for some reason.

The provision of the liquid collection vessel valves and the closing of those valves ensure that the reaction products can be securely prevented from flowing back into the processing apparatus, even if the flow of exhaust gases reverses. Furthermore, it is also possible to expel the accumulated substances automatically when a certain quantity of those accumulated substances has collected. The provision of the cleaning mechanism in the trap mechanism makes it possible to wash away the captured substances in a simpler manner, thus making it possible to improve the workability of the maintenance.

Finally, the provision of the trap mechanism and the inclination of the passageways in the downward direction make it possible to prevent any backflow of the reaction products captured by the trap mechanism.

What is claimed is:

1. An exhaust system for a processing apparatus for subjecting an object to be processed to a predetermined processing with a processing gas, said exhaust system comprising:
a vacuum exhaust pathway connected to said processing apparatus;
a vacuum pump provided in said vacuum exhaust pathway, for evacuating said processing apparatus;
a trap mechanism for removing reaction products that are generated within said processing apparatus and flow into said vacuum exhaust pathway, said trap mechanism being provided within said vacuum exhaust pathway, so as to divide the pathway into an upstream-side section and a downstream-side section;
an upstream connection device for removably linking an inlet portion of said trap mechanism to said upstream-side section of the exhaust pathway;
a downstream connection device for removably linking an outlet portion of said trap mechanism to said downstream-side section of the exhaust pathway;
an inlet-side isolation valve and an outlet-side isolation valve connected in a closable manner to said inlet portion and said outlet portion of said trap mechanism, for placing an interior of said trap mechanism in a hermetically sealed state; and
a bypass pathway for connecting said upstream-side section and said downstream-side section of the vacuum exhaust pathway, bypassing said upstream connection device, said trap mechanism, and said outlet-side isolation valve, to allow a cleaning gas to bypass said trap mechanism and flow through said vacuum exhaust pathway during the cleaning of said processing apparatus.

2. The exhaust system for a processing apparatus as defined in claim 1, further comprising a shut-off valve provided on an immediately upstream side of said upstream-side connection device within said upstream-side section of the vacuum exhaust pathway.

3. The exhaust system for a processing apparatus as defined in claim 1, further comprising a reverse-flow prevention valve provided on an immediately downstream side of said downstream-side connection device within said downstream-side section of said vacuum exhaust pathway.

4. The exhaust system for a processing apparatus as defined in claim 1, further comprising a bypass valve in an upstream end portion of said bypass pathway.

5. The exhaust system for a processing apparatus as defined in claim 1, wherein said upstream-side connection device and said downstream-side connection device are connection flanges.

6. The exhaust system for a processing apparatus as defined in claim 1, further comprising a liquid collection vessel connected to said trap mechanism, for collecting the reaction products that have been captured as liquids therein.

7. The exhaust system for a processing apparatus as defined in claim 6, further comprising a liquid collection vessel valve provided between said trap mechanism and said liquid collection vessel, for controlling a flow of reaction products from said trap mechanism to said liquid collection vessel.

8. The exhaust system for a processing apparatus as defined in claim 6, further comprising a drain pipe within said liquid collection vessel, for expelling the reaction products that have collected as liquids therein.

9. The exhaust system for a processing apparatus as defined in claim 6, further comprising an accumulated substances sensor for detecting the quantity of reaction products accumulated within said liquid collection vessel.

10. The exhaust system for a processing apparatus as defined in claim 1, further comprising a cleaning mechanism within said trap mechanism, for washing away liquefied reaction products that have been captured therein.

11. The exhaust system for a processing apparatus as defined in claim 1, wherein said vacuum exhaust pathway is inclined downward at a predetermined angle towards the downstream side, in at least a portion thereof in which said trap mechanism is provided.

12. The exhaust system for a processing apparatus as defined in claim 1, wherein said trap mechanism is provided with a trap vessel and said trap vessel has a bottom surface that is inclined downward at a predetermined angle from an inlet thereof towards an outlet thereof.
